(19) United States
(12) Patent Application Publication
(10) Pub. No.: US 2023/0305061 A1
(43) Pub. Date: Sep. 28, 2023

(54) DEVICE FOR AUTONOMOUS CHARGING BATTERY AND METHOD FOR AUTONOMOUS CHARGING BATTERY

(71) Applicants: Futaijing Precision Electronics (Yantai) Co., Ltd., Yantai (CN); HON HAI PRECISION INDUSTRY CO., LTD., New Taipei (TW)

(72) Inventors: YEN-CHEN CHEN, New Taipei (TW); CHUN-YUAN CHIEN, New Taipei (TW)

(21) Appl. No.: 17/718,308

(22) Filed: Apr. 11, 2022

(30) Foreign Application Priority Data
Mar. 23, 2022 (CN) 202210295323.2

(51) Int. Cl. G01R 31/36; H02J 7/00

(52) U.S. Cl. CPC G01R 31/3648; H02J 7/007182; H02J 7/0032

(57) ABSTRACT

A device to control the charging or cessation of charging a robot battery is installed in a robot. The device for autonomous charging battery includes the robot battery, a charging mechanism, a relay, a first controller, and a second controller. The relay is electrically connected with the charging mechanism and the first controller, the battery is electrically connected with the charging mechanism, the second controller communicates with the first controller, and the charging mechanism is used for electrically connecting an external charging device. The second controller is configured to receive the robot control command and output the relay control command to the first controller based on the robot control command. The first controller is configured to switch the relay on or off based on the control command to control charging or cessation of charging. A method of autonomous charging battery is also provided.

### FIELD

The subject matter herein generally relates to autonomous robot control, especially relates to a device for autonomous charging battery and a method for autonomous charging battery applied to robots.

### BACKGROUND

Autonomous charging is a feature of automated guided vehicles (AGVs) and automated mobile robots (AMRs). It can enable the robot to automatically return to the charging station for charging when the internal battery is almost dead, and automatically return to the original working area when the battery is fully charged.

However, if the robot needs to return to the original working area before a full charge is taken, the system needs to command the battery to stop charging through CAN bus, which not only increases the complexity of software development, but also increase the complexity of safety assessment.

### SUMMARY

The disclosure provides a device for autonomous charging battery and a method for autonomous charging a battery employed in a robot, to control a charging mechanism to charge or stop charging the battery through the combination of a relay and a controller. The structure is simple and easy to realize, which can improve the charging safety of the robot.

A device for autonomous charging battery employed to a robot, comprises a battery, a charging mechanism, a relay, a first controller, and a second controller. The relay is electrically connected with the charging mechanism and the first controller, the battery is electrically connected with the charging mechanism, the second controller is connected with the first controller, and the charging mechanism is used for electrical connection to an external charging device. The second controller is configured to receive the robot control command and outputs the relay control command to the first controller based on the robot control command.

In an embodiment, the first controller is configured to switch the relay on or off based on the control command to control the charging mechanism to charge or stop charging the battery.

In an embodiment, the robot control command comprises at least one of a robot charging command and a robot power-off command; when the controller receives the robot charging command, the first controller controls the relay to turn on, to charge the battery through an external charging device. When the second controller receives the robot power-off command, the first controller controls the relay to disconnect the charging mechanism and stop charging the battery.

In an embodiment, the first controller comprises an output terminal, the relay comprises a control terminal, and the output terminal is electrically connected with the control terminal; when the second controller receives the robot charging command, the output of the first controller is at a high voltage, and the relay is turned on to enable the external charging device to charge the battery through the charging mechanism; when the second controller receives the robot power-off command, the output terminal is low voltage and the relay is disconnected, so that the charging mechanism stops charging the battery.

In an embodiment, the device for autonomous charging battery further comprises a communication module for receiving the robot control command and transmitting the robot control command to the second controller.

In an embodiment, the first controller is a programmable logic controller and the second controller is an industrial control computer.

In an embodiment, the first controller and the second controller are connected through a network line.

In an embodiment, the relay is a solid-state relay.

The charging mechanism can be electrically connected to an external charging device and the battery; the second controller is configured to receive the robot control command and output the relay control command to the first controller based on the robot control command. The first controller is configured to control the relay to be on or off based on the relay control command to charge or disconnect from the battery though the external charging device.

In an embodiment, the robot control command comprises at least one of a robot charging command and a robot power-off command; when the controller receives the robot charging command, the first controller controls the relay to turn on to charge the battery through an external charging device; when the second controller receives the robot power-off command, the first controller controls the relay to disconnect and stop charging the battery.

In an embodiment, the first controller comprises an output terminal, the relay comprises a control terminal, and the output terminal is electrically connected with the control terminal; when the second controller receives the robot charging command, the output of the first controller is at a high voltage, and the relay is turned on to enable the external charging device to charge the battery through the charging mechanism; when the second controller receives the robot power-off command, the output terminal is low voltage and the relay is disconnected, so that the charging mechanism stops charging the battery.

In an embodiment, the controlling device further comprises a communication module for transmitting the robot control command to the second controller.

In an embodiment, the first controller is a programmable logic controller and the second controller is an industrial control computer.

In an embodiment, the first controller and the second controller are connected through a network line.

In an embodiment, the relay is a solid-state relay.

A method for autonomous charging battery, employed in a robot, receives a robot control command; outputs a relay control command based on the robot control command; the relay is switched on or switched off based on the relay control command to control the charging mechanism to charge or stop charging the battery.

In an embodiment, the step of outputting a relay control command based on the robot control command comprises: when the robot control command is a robot charging command, a command of turning on the relay is output based on a robot charging command; when the robot control command is a robot power-off command, a command of turning off the relay is output based on the robot power-off command.

In an embodiment, the command of turning on the relay is a high voltage and the command of turning off the relay is a low voltage.

LABEL OF COMPONENTS

| | |
|---|---|
| device for autonomous charging battery | 10 |
| battery | 11 |
| charging mechanism | 12 |
| relay | 13 |
| first controller | 14 |
| second controller | 15 |
| communication module | 16 |

### BRIEF DESCRIPTION OF THE DRAWINGS

Implementations of the present technology will now be described, by way of embodiments with reference to the attached figures.

FIG. 1 is a schematic diagram of a device for autonomous charging battery.

FIG. 2 is a flowchart of a method for autonomous charging battery.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better show details and features of the present disclosure. The disclosure is by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. References to “a plurality of” and “a number of” mean “at least two.”

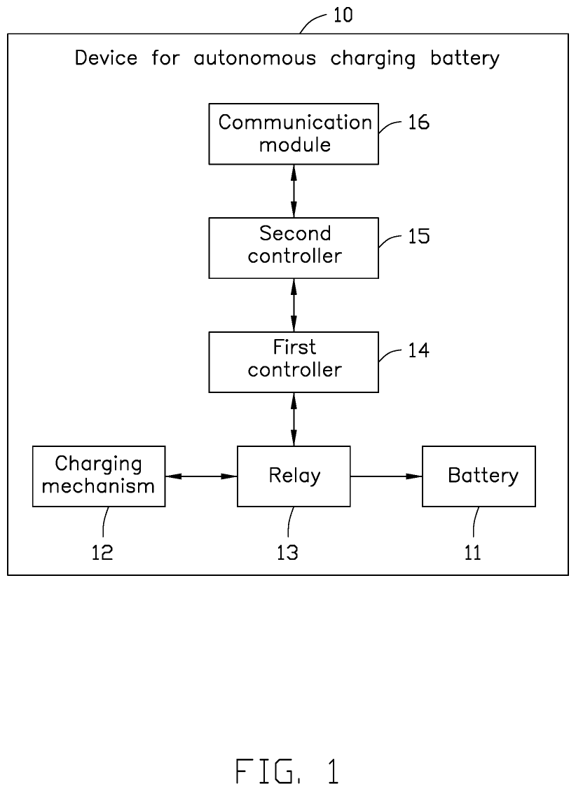

Referring to FIG. 1, the disclosure discloses a device for autonomous charging battery 10.

The device for autonomous charging battery 10 is configured to be applied to a robot. The robot can be an automated guided vehicle (AGV) or automated mobile robot (AMR) or other related type of robot.

The device for autonomous charging battery 10 includes a battery 11, a charging mechanism 12, a relay 13, a first controller 14, and a second controller 15. The relay 13 is electrically connected with the charging mechanism 12 and the first controller 14. The battery 11 is electrically connected with the charging mechanism 12. The second controller 15 communicates with the first controller 14. The charging mechanism 12 is used to electrically connect the external charging device. The second controller 15 is used to receive robot control commands and output relay control commands to the first controller 14 based on the robot control commands. The first controller 14 is used to control the relay 13 to turn on or off based on the relay control command to control the charging mechanism 12 to charge or stop charging the battery 11.

In this embodiment, the robot control command is sent by the external terminal device, which is in communication with the robot. The user can send the corresponding robot control command to the second controller 15 according to the actual working requirements of the robot, so as to control the relevant operation of the robot.

In one embodiment, the robot control command includes at least one of a robot charging command and a robot power-off command.

In one embodiment, when the robot is running out of power in the battery 11, the robot can be controlled to automatically electrically connect the external charging device, and the external terminal device can send the robot charging command to the second controller 15. When the second controller 15 receives the robot charging command, the first controller 14 controls the relay 13 to turn on so that an external charging device charges the battery 11 through the charging mechanism 12.

In one embodiment, when the robot needs to temporarily return to the original working area during charging, the external terminal device can send the robot power-off command to the second controller 15. When the second controller 15 receives the robot power-off command, the first controller 14 controls the relay 13 to disconnect so that the charging mechanism 12 stops charging the battery 11.

In one embodiment, the first controller 14 includes an output terminal, the relay 13 includes a control terminal, and the output terminal is electrically connected with the control terminal.

In one embodiment, when the second controller 15 receives the robot charging command, the output of the first controller 14 is at a high voltage, and the relay 13 is turned on to enable the external charging device to charge the battery 11 through the charging mechanism 12.

In one embodiment, when the second controller 15 receives the robot power-off command, the output terminal is low voltage and the relay 13 is disconnected, so that the charging mechanism 12 stops charging the battery 11.

In this embodiment, the charging mechanism 12 can comprise four charging copper blocks, representing the charging positive electrode, CANH (high voltage), CANL (low voltage) and charging negative electrode respectively. Correspondingly, the external charging device can comprise four charging copper blocks, representing the charging positive pole, CANH (high voltage), CANL (low voltage) and charging negative pole respectively. The charging copper block on the charging mechanism 12 is matched with the charging copper block on the external charging device.

In one embodiment, the device for autonomous charging battery 10 further includes a communication module 16 for receiving the robot control command and transmitting the robot control command to the second controller 15. For example, the communication module 16 is a wireless communication module based on any one of WI-FI, ZIGBEE, RFID, or wireless USB wireless communication protocols.

In one embodiment, the first controller 14 is a programmable logic controller and the second controller 15 is an industrial control computer. In this embodiment, the first controller 14 is sick® brand programmable logic controller, which uses Q3 as the output terminal to control relay 13 with 24 VDC voltage. The first controller 14 and the second controller 15 can also be other type of controllers or control equipment according to the actual needs, which is not limited in the present application.

In one embodiment, the first controller 14 and the second controller 15 can be connected through a network line. In this embodiment, the first controller 14 and the second controller 15 can transmit instructions through a network line.

In one embodiment, the relay 13 is a solid-state relay. In this embodiment, the relay 13 can be a solid-state relay with a 30A resistor. In other embodiments, different types of relays 13 can be selected under different charging conditions.

The device for autonomous charging battery 10 provided by the embodiment of the application can control the charging mechanism 12 to charge or stop charging the battery 11 through the combination of the relay 13 and the controller. It has simple structure and is easy to implement, and can improve the charging safety of the robot.

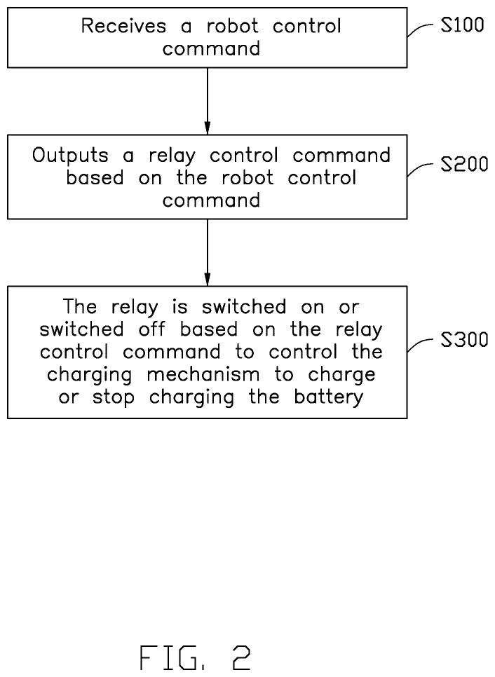

Referring to FIG. 2, a method for autonomous charging battery is provided.

In one embodiment, the control method is applied to a robot, which comprises a battery 11, a charging mechanism 12, and a relay 13. The method includes following steps.

S100, receives a robot control command.

S200, outputs a relay control command based on the robot control command.

S300, the relay is switched on or switched off based on the relay control command to control the charging mechanism to charge or stop charging the battery.

In one embodiment, when the robot control command is a robot charging command, a command of turning on the relay 13 is output based on the robot charging command.

In one embodiment, when the robot control command is a robot power-off command, a command of turning off the relay 13 is output based on the robot power-off command.

In one embodiment, the command of turning on the relay 13 is a high voltage and the command of turning off the relay 13 is a low voltage.

The device for autonomous charging battery 10 and method provided in the embodiment of the application control the charging mechanism 12 to charge or stop charging of the battery 11 through the combination of the relay 13 and the controller. The structure is simple and easy to implement, and the charging safety of the robot can be improved.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A device for autonomous charging battery employed to a robot, comprising:
a battery, a charging mechanism, a relay, a first controller and a second controller;
wherein the relay is electrically connected with the charging mechanism and the first controller, the battery is electrically connected with the charging mechanism, the second controller is communicatively connected with the first controller, and the charging mechanism is used for electrically connecting an external charging device;
the second controller is configured to receive the robot control command and outputting the relay control command to the first controller based on the robot control command;
the first controller is configured to control the relay on or off based on the relay control command to control the charging mechanism to charge or stop charging the battery.

2. The device for autonomous charging battery of claim 1, wherein the robot control command comprises at least one of a robot charging command and a robot power-off command; when the controller receives the robot charging command, the first controller controls the relay to turn on to charge the charges the battery through an external charging device; when the second controller receives the robot power-off command, the first controller controls the relay to disconnect to control the charging mechanism stops charging the battery.

3. The device for autonomous charging battery of claim 2, wherein the first controller comprises an output terminal, the relay comprises a control terminal, and the output terminal is electrically connected with the control terminal; when the second controller receives the robot charging command, the output of the first controller is at a high voltage, and the relay is turned on to enable the external charging device to charge the battery through the charging mechanism; when the second controller receives the robot power-off command, the output terminal is low voltage and the relay is disconnected, so that the charging mechanism stops charging the battery.

4. The device for autonomous charging battery of claim 1, wherein the device for autonomous charging battery further comprises a communication module for receiving the robot control command and transmitting the robot control command to the second controller.

5. The device for autonomous charging battery of claim 1, wherein the first controller is a programmable logic controller and the second controller is an industrial control computer.

6. The device for autonomous charging battery of claim 5, wherein the first controller and the second controller is connected through a network line.

7. The device for autonomous charging battery of claim 1, wherein the relay is a solid-state relay.

8. An device for autonomous charging battery employed to a robot, comprising:
a battery, a charging mechanism, a relay, a first controller and a second controller;
wherein the relay is electrically connected with the charging mechanism and the first controller, the battery is electrically connected with the charging mechanism, the second controller is communicatively connected with the first controller, and the charging mechanism is configured to electrically connecting an external charging device and the battery;
the second controller is configured to receive the robot control command and outputting the relay control command to the first controller based on the robot control command;
the first controller is configured to control the relay on or off based on the relay control command to charge or discharge the battery though the external charging device.

9. The device for autonomous charging battery of claim 8, wherein the robot control command comprises at least one of a robot charging command and a robot power-off command; when the controller receives the robot charging command, the first controller controls the relay to turn on to charge the charges the battery through an external charging device; when the second controller receives the robot power-off command, the first controller controls the relay to disconnect to control the charging mechanism stops charging the battery.

10. The device for autonomous charging battery of claim 9, wherein the first controller comprises an output terminal, the relay comprises a control terminal, and the output terminal is electrically connected with the control terminal; when the second controller receives the robot charging command, the output of the first controller is at a high voltage, and the relay is turned on to enable the external charging device to charge the battery through the charging mechanism; when the second controller receives the robot power-off command, the output terminal is low voltage and the relay is disconnected, so that the charging mechanism stops charging the battery.

11. The device for autonomous charging battery of claim 8, wherein the device for autonomous charging battery further comprises a communication module for receiving the robot control command and transmitting the robot control command to the second controller.

12. The device for autonomous charging battery of claim 8, wherein the first controller is a programmable logic controller and the second controller is an industrial control computer.

13. The device for autonomous charging battery of claim 12, wherein the first controller and the second controller is connected through a network line.

14. The device for autonomous charging battery of claim 8, wherein the relay is a solid-state relay.

15. A method for autonomous charging battery, employed in a robot, the method comprising:
receives a robot control command;
outputs a relay control command based on the robot control command;
the relay is switched on or switched off based on the relay control command to control the charging mechanism to charge or stop charging the battery.

16. The method of claim 15, wherein the step “outputs a relay control command based on the robot control command” comprises:
when the robot control command is a robot charging command, a command of turning on the relay is output based on a robot charging command;
when the robot control command is a robot power-off command, a command of turning off the relay is output based on the robot power-off command.

17. The method of claim 16, wherein the command of turning on the relay is a high voltage and the command of turning off the relay is a low voltage.
